(19) United States
(12) Patent Application Publication
(10) Pub. No.: US 2026/0312542 A1
(43) Pub. Date: Oct. 8, 2026

(54) MULTISTAGE AMPLIFIER

(71) Applicant: NTT, Inc., Tokyo (JP)

(72) Inventor: Tadashi Minotani, Tokyo (JP)

(21) Appl. No.: 19/480,492

(22) PCT Filed: May 26, 2023
(86) PCT No.: PCT/JP2023/019702

§ 371 Date: Oct. 31, 2025

(51) Int. Cl. H03F 1/02; H03F 3/60

(52) U.S. Cl. CPC H03F 1/0233; H03F 3/604; H03F 2200/462; H03F 2200/504

(57) ABSTRACT

The present disclosure provides a multistage amplifier circuit connected to a power supply line. The multistage amplifier circuit includes a multistage amplifier in which a plurality of inverting amplifiers are connected in multiple stages, each including p-type MOS transistors and n-type MOS transistors connected in series, and a power supply AC current balancing circuit connected to an output of a final-stage inverting amplifier among the plurality of inverting amplifiers. The power supply AC current balancing circuit includes another p-type MOS transistor and another n-type MOS transistor connected in series, and a resistor connected between drains of the other p-type MOS transistor and the other n-type MOS transistor and a bias voltage.

### CROSS-REFERENCE TO RELATED APPLICATIONS

This application is a national phase entry of PCT Application No. PCT/JP2023/019702, filed on May 26, 2023, which application is hereby incorporated herein by reference.

### TECHNICAL FIELD

The present invention relates to a multistage amplifier circuit having good frequency characteristics.

### BACKGROUND

In communication of electrical signals or optical signals, codes such as NRZ and PAM4, which are baseband signals, are used (Non Patent Literature 1), and have the advantage of a simple configuration of a transmission and reception circuit and low delay. Both the electrical signal and the optical signal are subjected to amplification processing on the receiving side.

In a case where the attenuation of the signal in the communication path is large, the signal amplitude decreases, and thus, it is necessary to increase the gain of the signal amplification. Therefore, the amplifier circuit for a baseband signal is configured as a multistage amplifier circuit in which a plurality of circuits are connected in series.

### CITATION LIST

### Non Patent Literature

Non Patent Literature 1: Motofumi KAWANISHI, “Kosoku Intafesu De Shiyo Sareru SerDes~Shurui To Tokucho, Sono Rekisi (in Japanese) (SerDes used in high-speed interfaces: types, features and history)” EDN Japan, May 11, 2018, <URL: https://edniapan.com/edn/articles/1805/11/news018_4.html>

### SUMMARY

### Technical Problem

However, in a case where the multistage amplifier circuit is composed of a single-ended circuit such as an inverter amplifier or a grounded emitter amplifier circuit, there is a problem in that resonance caused by the parasitic inductance of the power supply line and the capacitance between the power supply line and ground causes peaks and dips on the low-frequency side of the frequency characteristics, resulting in waveform degradation.

### Solution to Problem

In order to solve the problems described above, a multistage amplifier circuit according to the present invention is a multistage amplifier circuit connected to a power supply line, the multistage amplifier circuit including: a multistage amplifier in which a plurality of inverting amplifiers are connected in multiple stages, each including p-type MOS transistors and n-type MOS transistors connected in series; and a power supply AC current balancing circuit connected to an output of a final-stage inverting amplifier among the plurality of inverting amplifiers, in which the power supply AC current balancing circuit includes: another p-type MOS transistor and another n-type MOS transistor connected in series; and a resistor connected between drains of the other p-type MOS transistor and the other n-type MOS transistor and a bias voltage.

### Advantageous Effects of Invention

According to the present invention, it is possible to provide a multistage amplifier circuit having good frequency characteristics.

### BRIEF DESCRIPTION OF THE DRAWINGS

FIG. 1 is a block diagram illustrating a configuration of a multistage amplifier circuit according to a first embodiment of the present invention.

FIG. 2 is a diagram for describing an operation of the multistage amplifier circuit according to the first embodiment of the present invention.

FIG. 3 is a diagram for describing an operation of the multistage amplifier circuit according to the first embodiment of the present invention.

FIG. 4A is a diagram for describing an operation of the multistage amplifier circuit according to the first embodiment of the present invention.

FIG. 4B is a diagram for describing an operation of the multistage amplifier circuit according to the first embodiment of the present invention.

FIG. 5A is a diagram for describing an operation of the multistage amplifier circuit according to the first embodiment of the present invention.

FIG. 5B is a diagram for describing an operation of the multistage amplifier circuit according to the first embodiment of the present invention.

FIG. 6A is a diagram for describing an operation of the multistage amplifier circuit according to the first embodiment of the present invention.

FIG. 6B is a diagram for describing an operation of the multistage amplifier circuit according to the first embodiment of the present invention.

FIG. 7 is a diagram for describing an operation of the multistage amplifier circuit according to the first embodiment of the present invention.

FIG. 8 is a diagram for describing an operation of the multistage amplifier circuit according to the first embodiment of the present invention.

FIG. 9 is a diagram for describing an operation of the multistage amplifier circuit according to the first embodiment of the present invention.

FIG. 10 is a diagram for describing an operation of the multistage amplifier circuit according to the first embodiment of the present invention.

FIG. 11A is a diagram for describing an operation of the multistage amplifier circuit according to the first embodiment of the present invention.

FIG. 11B is a diagram for describing an operation of the multistage amplifier circuit according to the first embodiment of the present invention.

FIG. 12 is a block diagram illustrating a configuration of a multistage amplifier circuit according to a second embodiment of the present invention.

FIG. 13 is a diagram for describing an operation of the multistage amplifier circuit according to the second embodiment of the present invention.

FIG. 14 is a block diagram illustrating a configuration of a multistage amplifier circuit according to a third embodiment of the present invention.

### DETAILED DESCRIPTION OF ILLUSTRATIVE EMBODIMENTS

### First Embodiment

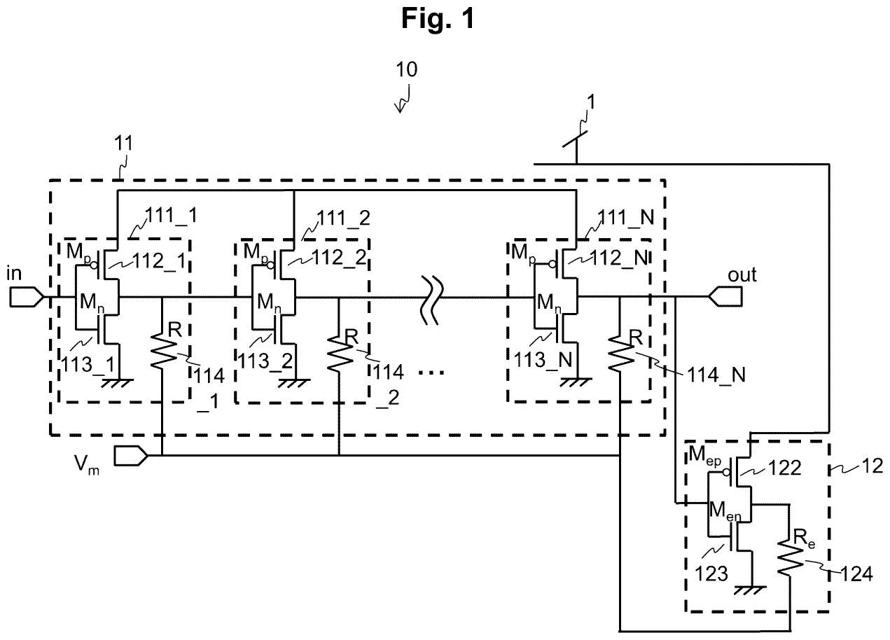

A multistage amplifier circuit according to a first embodiment of the present invention will be described with reference to FIGS. 1 to 11B.

### <Configuration of Multistage Amplifier Circuit>

As illustrated in FIG. 1, a multistage amplifier circuit 10 according to the present embodiment includes a multistage amplifier 11 and a power supply AC current balancing circuit 12.

The multistage amplifier 11 includes a plurality of stages (N stages) of inverting amplifiers 111_1 to 111_N (gain: G). In each of the inverting amplifiers 111_1 to 111_N, p-type MOS transistors Mₚ 112_1 to 112_N and n-type MOS transistors Mₙ 113_1 to 113_N are connected in series between a power supply 1 and the ground.

In the inverting amplifiers 111_1 to 111_N, the gates of the p-type MOS transistors Mₚ 112_1 to 112_N and the n-type MOS transistors Mₙ 113_1 to 113_N are used as inputs (in), and the drains of the p-type MOS transistors Mₚ 112_1 to 112_N and the n-type MOS transistors Mₙ 113_1 to 113_N are used as outputs (out).

Resistors R 114_1 to 114_N are connected between the output (the drains of the p-type MOS transistors Mₚ 112_1 to 112_N and the n-type MOS transistors Mₙ 113_1 to 113_N) and a bias voltage Vₘ supplied from a bias voltage source (not shown).

The width of the p-type MOS transistors Mₚ 112_1 to 112_N is wₚ, and the width of the n-type MOS transistors Mₙ 113_1 to 113_N is wₙ. Hereinafter, the “width of a MOS transistor” refers to the length in the direction perpendicular to the gate length direction.

The power supply AC current balancing circuit 12 includes a p-type MOS transistor Mₑₚ 122 (also referred to as a “p-type MOS transistor for balancing circuit” or “another p-type MOS transistor”), an n-type MOS transistor Mₑₙ 123 (also referred to as an “n-type MOS transistor for balancing circuit” or “another n-type MOS transistor”), and a load resistor Rₑ 124.

The p-type MOS transistor Mₑₚ 122 and the n-type MOS transistor Mₑₙ 123 are connected in series between the power supply 1 and the ground. The gates of the p-type MOS transistor Mₑₚ 122 and the n-type MOS transistor Mₑₙ 123 are connected to the output of the inverting amplifier in the final stage among the inverting amplifiers 111_1 to 111_N constituting the multistage amplifier 11.

The load resistor Rₑ 124 is connected between the drains of the Mₑₚ 122 and the Mₑₙ 123 and the bias voltage Vₘ.

### <Operation of Multistage Amplifier Circuit>

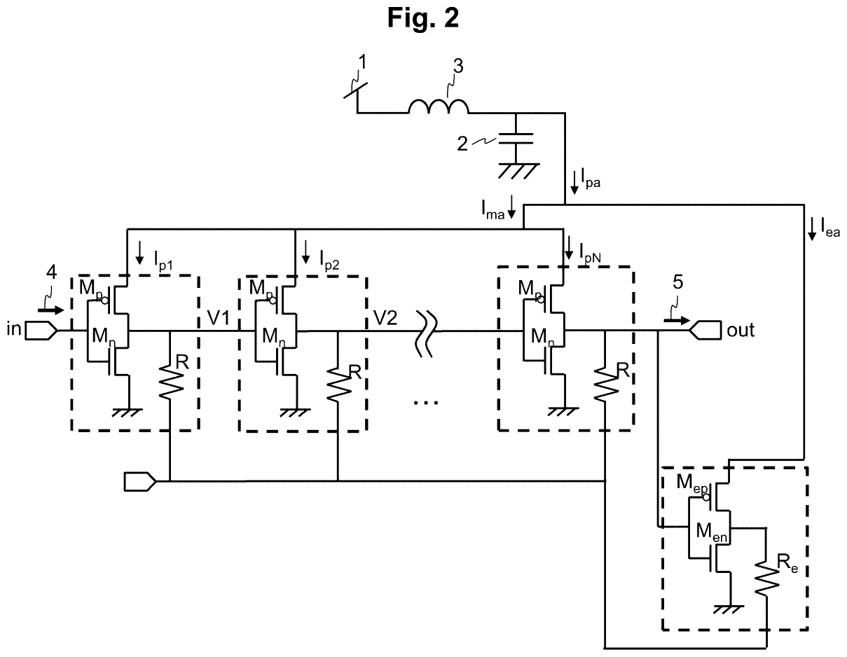

The operation of the multistage amplifier circuit 10 according to the present embodiment will be described with reference to FIGS. 2 to 11B.

In the multistage amplifier circuit 10, as illustrated in FIG. 2, when the amplitude of an input signal 4 of the multistage amplifier 11 biased to the operation region decreases, an output V₁ of the inverting amplifier 111_1 increases, and a current Iₚ₁ flowing through Mₚ 112_1 to 112_N of the inverting amplifier 111_1 increases.

Subsequently, when the output V₁ of the inverting amplifier 111_1 is input to the inverting amplifier 111_2, an output V₂ of the inverting amplifier 111_2 decreases, and a current Iₚ₂ flowing through Mₚ 112_1 to 112_N of the inverting amplifier 111_2 decreases. The magnitudes of changes in Iₚ₁ and Iₚ₂ are positively correlated with the amplitudes of V₁ and V₂, respectively.

In a case where the gain G of the inverting amplifier in one stage in the multistage amplifier 11 is larger than 1, the amplitude of the output to the inverting amplifier in the subsequent stage is large.

In addition, the change in the current (increase or decrease) flowing through each inverting amplifier 111_n (for example, the nth stage) and the inverting amplifiers 111_n−1 and 111_n+1 (for example, the (n−1)th stage and the (n+1)th stage) before and after the inverting amplifier is reversed. For example, when the current flowing through the inverting amplifier 111_n in the Nth stage increases, the current flowing through the inverting amplifiers 111_n−1 and 111_n+1 of the (n−1)th stage and the (n+1)th stage decreases.

Therefore, the change in the current flowing through the inverting amplifiers 111_n−1 and 111_n+1 (for example, the (n−1)th stage or (n+1)th stage) before or after each inverting amplifier 111_n (for example, the nth stage) is cancelled out.

As a result, the change in an AC current Iₘₐ flowing through the multistage amplifier 11 depends on the currents flowing through Mₚ 112_1 to 112_N of the final-stage inverting amplifier 111_N having a large output amplitude. In this manner, the Iₘₐ changes according to the amplitude of the input signal 4.

In the power supply line of a conventional amplifier, for example, a decoupling capacitor is connected to stabilize the power supply voltage. Furthermore, the parasitic inductance present on the power supply line and the decoupling capacitor form a resonant circuit. In a case where the input signal 4 is a wideband signal such as a baseband signal, the frequency characteristic of Iₘₐ also becomes wideband. Here, an example in which a decoupling capacitor is provided has been shown, but the present invention is not limited thereto, and a parasitic capacitance may be present instead of the decoupling capacitor.

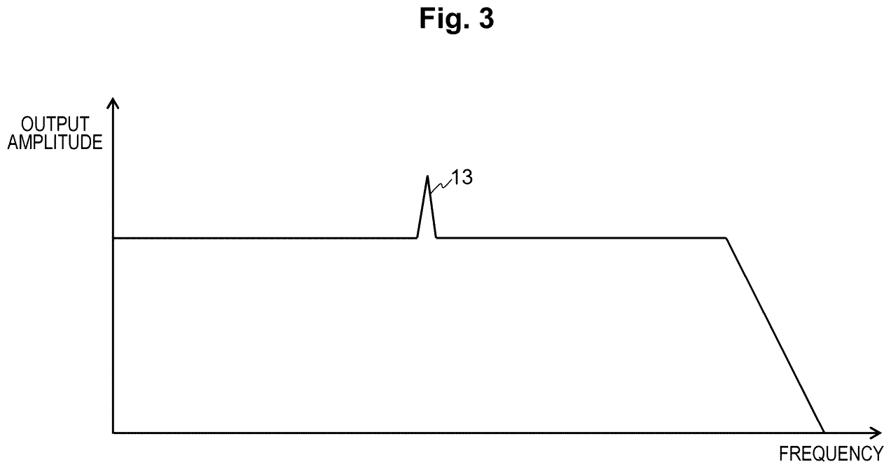

In a conventional amplifier, when Iₚₐ flowing through the above-mentioned resonant circuit changes, the power supply voltage of the multistage amplifier 11 fluctuates at the resonant frequency of the resonant circuit, and the frequency characteristic of the output signal 5 of the multistage amplifier 11 exhibits a peak 13 or a dip (not shown) due to the resonance of the resonant circuit, as illustrated in FIG. 3.

In the multistage amplifier circuit according to the present embodiment, the input of the power supply AC current balancing circuit 12 is connected to the output of the inverting amplifier in the final stage of the multistage amplifier 11. The output of the power supply AC current balancing circuit 12 is an inverted signal of the output of the multistage amplifier 11.

As a result, the change in a balanced AC current Iₑₐ flowing through the Mₑₚ 122 of the power supply AC current balancing circuit 12 and the change in the AC current Iₘₐ flowing through the multistage amplifier 11 are in opposite phases. Therefore, the change in Iₑₐ can cancel out the change in Iₘₐ.

This suppresses the change in a power supply AC current Iₚₐ, which is the sum of Iₘₐ and lea, according to the input signal 4. As a result, changes in the current (Iₚₐ) flowing through the resonant circuit formed in the power supply line of the amplifier are suppressed, and the occurrence of peaks or dips in the frequency characteristics of the output signal 5 of the multistage amplifier 11 due to the resonant circuit formed in the power supply line is suppressed. In this way, the multistage amplifier circuit has good frequency characteristics.

Furthermore, by making the AC current Iₘₐ flowing through the multistage amplifier 11 and the balanced AC current Iₑₐ flowing through the Mₑₚ 122 of the power supply AC current balancing circuit 12 substantially equal to each other, the power supply AC current Iₚₐ, which is the sum of Iₘₐ and Iₑₐ, can be suppressed. Here, “substantially equal to each other” includes equality, and also includes the case where the relationship (difference) between Iₘₐ and Iₑₐ is within a range that can suppress the occurrence of peaks or dips due to the resonant circuit formed in the power supply line in the frequency characteristics of the output signal of the multistage amplifier 11. The details are described below.

In the multistage amplifier circuit, the larger the current flowing through Mₚ 112_1 to 112_N of the inverting amplifiers 111_1 to 111_N, the larger the change in Iₘₐ. The wider the width wₚ of Mₚ 112_1 to 112_N and the width wₙ of Mₙ 113_1 to 113_N, the larger the current flowing through Mₚ 112_1 to 112_N of the inverting amplifiers 111_1 to 111_N, and therefore the larger the change in Iₘₐ.

Furthermore, the smaller the resistors R 114_1 to 114_N, the current flowing through Mₚ 112_1 to 112_N of the inverting amplifiers 111_1 to 111_N increases in accordance with the increase in the current flowing through the output side of the inverting amplifiers 111_1 to 111_N. Therefore, the smaller the resistors R 114_1 to 114_N, the larger the change in Iₘₐ.

In a case where the change in Iₘₐ is large, it is necessary to increase Iₑₐ to cancel out Iₘₐ. Therefore, the width Wₑₚ of Mₑₚ 122 and the width Wₑₙ of Mₑₙ 123 are set wide, and Rₑ is set small.

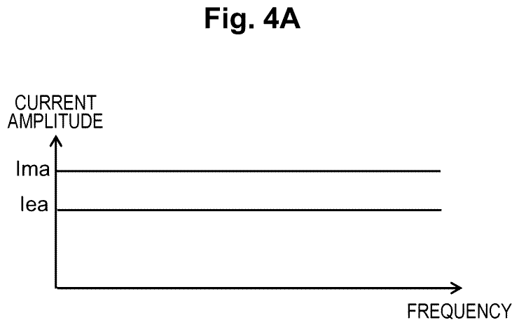

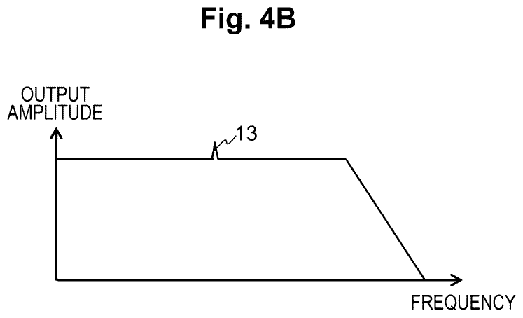

In the multistage amplifier circuit 10, the frequency characteristics of Iₘₐ, Iₑₐ, and output amplitude when the sum of Wₑₚ and Wₑₙ (Wₑₚ+Wₑₙ) is changed will be described. FIGS. 4A to 6B illustrate frequency characteristics according to changes in Wₑₚ+Wₑₙ in a multistage amplifier circuit having an even number of stages.

In the power supply AC current balancing circuit 12, Wᵢ, which is the sum of wₚ and wₙ (wₚ+wₙ), is set constant, and R 114_1 to 114_N of the inverting amplifiers 111_1 to 111_N are set constant.

In a case where Wₑ, which is the sum of Wₑₚ and Wₑₙ (Wₑₚ+Wₑₙ), is narrow, Iₘₐ>Iₑₐ (FIG. 4A). At this time, the frequency characteristic of the output amplitude of the multistage amplifier circuit has a peak due to the resonant circuit formed in the power supply line (FIG. 4B).

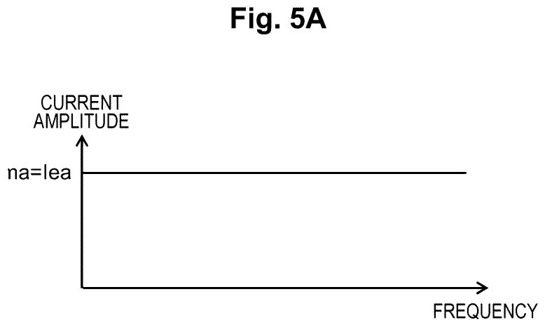

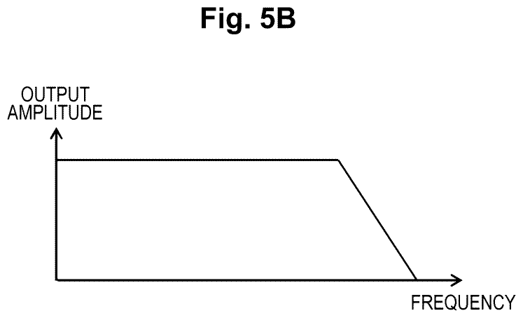

In a case where Wₑ is appropriate, Iₘₐ=Iₑₐ (FIG. 5A). At this time, the frequency characteristic of the output amplitude does not have a peak due to the resonant circuit (FIG. 5B).

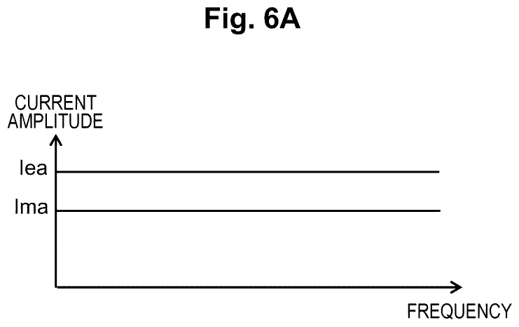

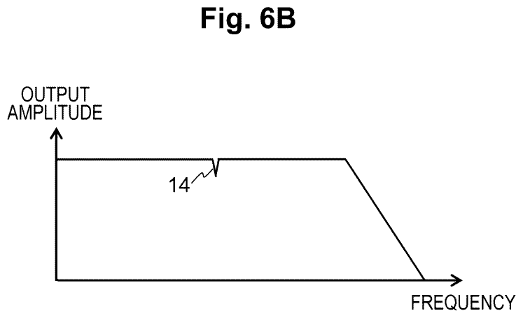

In a case where Wₑ is wide, Iₘₐ<Iₑₐ (FIG. 6A). At this time, the frequency characteristic of the output amplitude has a dip 14 due to the resonant circuit (FIG. 6B).

In addition, in a multistage amplifier circuit having an odd number of stages, in a case where Wₑ is narrow, a dip occurs in the frequency characteristics of the output amplitude due to the resonant circuit, and in a case where Wₑ is wide, a peak occurs in the frequency characteristics of the output amplitude due to the resonant circuit.

In this way, by setting Wₑ such that Iₘₐ=Iₑₐ, it is possible to realize good frequency characteristics in which the occurrence of peaks or dips due to the resonant circuit formed in the power supply line in the multistage amplifier circuit is suppressed.

Next, the relationship between Wₑ and the load resistor Rₑ when Iₘₐ=Iₑₐ in the power supply AC current balancing circuit 12 will be described. Let Wₑ (Iₘₐ=Iₑₐ) be Wₑ when Iₘₐ=Iₑₐ.

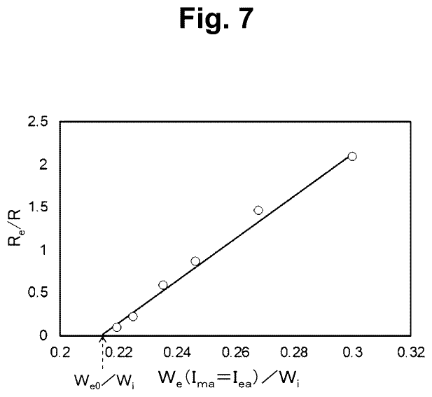

FIG. 7 shows the results of calculating the relationship between Wₑ (Iₘₐ=Iₑₐ)/Wᵢ and Rₑ/R. For the calculations, a simulator (product name: Cadence Spectre, manufactured by Cadence Design Systems, Inc.) was used. Here, G, Wᵢ, and R of the inverting amplifiers 111_1 to 111_N constituting the multistage amplifier 11 are set constant.

Wₑ (Iₘₐ=Iₑₐ)/Wᵢ changes with changes in the load resistor Rₑ 124. When Rₑ decreases, Wₑ (Iₘₐ=Iₑₐ) decreases. This is because when Rₑ is small, the change in Iₑₐ tends to be large, such that in order to make Iₘₐ=Iₑₐ, it is necessary to reduce Wₑ and suppress the change in Iₑₐ.

This indicates that Iₘₐ and Iₑₐ can be made substantially equal by changing the load resistor Rₑ 124.

In this way, by setting the load resistor Rₑ 124 such that Iₘₐ=Lea, it is possible to realize good frequency characteristics in which the occurrence of peaks or dips due to the resonant circuit formed in the power supply line in the multistage amplifier circuit is suppressed.

Next, the setting of Wₑ in the power supply AC current balancing circuit in the multistage amplifier circuit according to the present embodiment will be described.

Wₑₚ/Wₑₙ in the power supply AC current balancing circuit is substantially equal to wₚ/wₙ in the multistage amplifier. Here, Wₑₚ/Wₑₙ is the ratio of the width Wₑₚ of the p-type MOS transistor Mₑₚ to the width Wₑₙ of the n-type MOS transistor Mₑₙ in the power supply AC current balancing circuit. wₚ/wₙ is the ratio of the width wₚ of the p-type MOS transistor Mₚ to the width wₙ of the n-type MOS transistor Mₙ in the multistage amplifier.

In the following, for simplicity, the relationship between Wₑ (Iₘₐ=Iₑₐ)/Wᵢ and Rₑ/R is approximated by a straight line (solid line in FIG. 7), and Wₑ (Iₘₐ=Iₑₐ)/Wᵢ at Rₑ=0 is defined as Wₑₒ/Wᵢ.

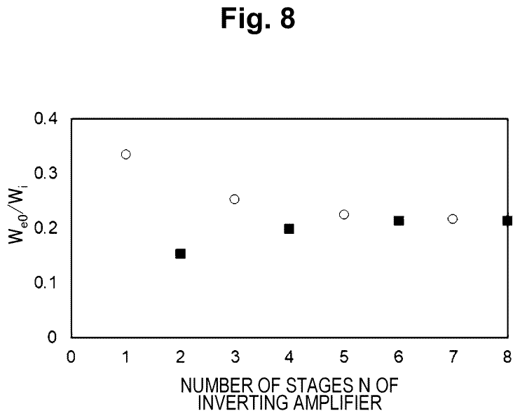

FIG. 8 illustrates the dependence of Wₑₒ/Wᵢ on the number of stages (N) of the multistage amplifier 11. G, Wᵢ, and R of the inverting amplifiers 111_1 to 111_N constituting the multistage amplifier 11 are set constant.

As the number of stages N increases, Wₑₒ/Wᵢ converges to a constant value. This is because the degree of cancellation of the change in Ip flowing through Mₚ 112_1 to 112_N of the inverting amplifiers 111_1 to 111_N in the front and rear stages is averaged. Since there are two types of changes in Ip flowing through Mₚ 112_1 to 112_N, that is, an increase or a decrease, the degree of cancellation between the front and rear stages is greater in a case where the number of stages N is an even number. In a case where the number of stages N is an odd number, one of the N stages does not participate in the cancellation of the currents when the front and rear stages cancel each other out, and therefore Iₘₐ is larger than in a case where the number of stages N is an even number. As a result, in a case where the number of stages N is an odd number, Wₑₒ/Wᵢ is larger than in a case where the number of stages N is an even number.

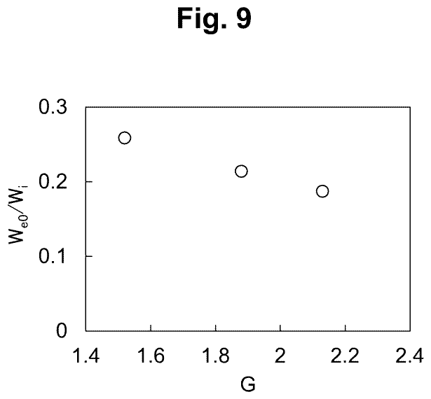

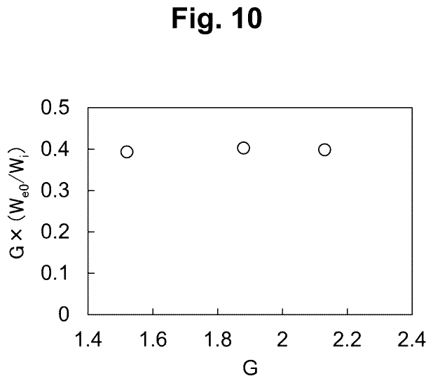

FIG. 9 shows the relationship between the gain G of the inverting amplifiers 111_1 to 111_N and Wₑₒ/Wᵢ in a case where the number of stages N of the inverting amplifiers 111_1 to 111_N of the multistage amplifier 11 is large (for example, N≥5). Wₑₒ/Wᵢ is inversely proportional to G. FIG. 10 illustrates the relationship between G×(Wₑₒ/Wᵢ) and G. G×(Wₑₒ/Wᵢ) is constant with respect to the change in G, and its value is 0.4.

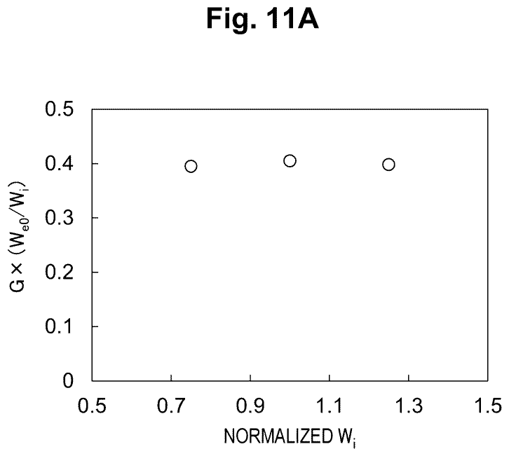

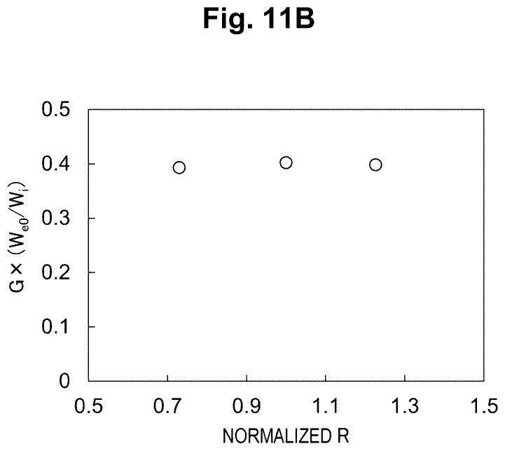

Since G depends on each of Wᵢ and R, the relationship between G×(Wₑₒ/Wᵢ) and each of Wᵢ and R will be described below. FIG. 11A illustrates the relationship between G×(Wₑₒ/Wᵢ) and Wᵢ in a case where R is constant. FIG. 11B illustrates the relationship between G×(Wₑₒ/Wᵢ) and Wᵢ in a case where Wᵢ is constant. In each of FIGS. 11A and 11B, the x axis represents normalized Wᵢ and normalized R. G×(Wₑₒ/Wᵢ) is constant with respect to the change in Wᵢ or R, and its value is 0.4.

Wₑₒ is the width of the MOS transistor in the power supply AC current balancing circuit 12 where Iₘₐ=Iₑₐ when Rₑ is 0. Even if Rₑ is not connected in an actual MOS transistor, there is a finite resistance value between the drains of the Mₑₚ 122 and the Mₑₙ 123 and the bias voltage Vₘ, and therefore the width Wₑ of the MOS transistor in the power supply AC current balancing circuit 12 is wider than Wₑₒ.

From FIG. 7, when Rₑ/R changes, Wₑ (Iₘₐ=Iₑₐ)/Wᵢ changes from 0.214 to 0.3. Wₑₒ/Wᵢ=0.214. Here, if Wₑ is too wide, the power consumption of the power supply AC current balancing circuit 12 will be high, and therefore it is desirable that Wₑ (Iₘₐ=Iₑₐ)/Wᵢ be less than 0.3.

Therefore, Wₑₒ/Wᵢ=0.214≤Wₑ/Wᵢ<0.3. In addition, G×(Wₑₒ/Wᵢ)=0.4. Therefore, from G×(Wₑ(Iₘₐ=Iₑₐ)/Wᵢ)={G×(Wₑₒ/Wᵢ)}×{(Wₑ(Iₘₐ=Iₑₐ)/Wᵢ)/(Wₑₒ/Wᵢ)}=0.4× (Wₑ(Iₘₐ=Iₑₐ)/Wᵢ)/(Wₑₒ/Wᵢ), G×(Wₑ(Iₘₐ=Iₑₐ)/Wᵢ) is expressed by Expression (1).

$$G \times ( {W}_{e 0} / {W}_{i} ) = 0.4 \leq G \times ( {W}_{e} ( {I}_{m a} = {I}_{e a} ) / {W}_{i} ) \leq 0.5 < 0.4 \times 0.3 / 0.214 \approx 0.561 \qquad ( 1 )$$

From FIG. 8, Wₑₒ/Wᵢ decreases as the number of stages N decreases. When the number of stages N is 2, since Wₑₒ/Wᵢ is 0.154, 0.154≤Wₑ (Iₘₐ=Iₑₐ)/Wᵢ≤0.214, and G×(Wₑ(Iₘₐ=Iₑₐ)/Wᵢ) is expressed by Expression (2).

$$0.4 \times 0.154 / 0.214 = 0.2 \; 88 < 0.3 \leq G ( {W}_{e} ( {I}_{m a} = {I}_{e a} ) / {W}_{i} ) \leq 0.4 \qquad ( 2 )$$

From Expressions (1) and (2), Wₑ (Iₘₐ=Iₑₐ)/Wᵢ satisfies 0.3≤G×Wₑ (Iₘₐ=Iₑₐ)/Wᵢ≤ 0.5.

As described above, in the multistage amplifier circuit according to the present embodiment, it is desirable that the sum Wₑ of the widths of the p-type and n-type MOS transistors in the power supply AC current balancing circuit satisfy 0.3≤G×Wₑ (Iₘₐ=Iₑₐ)/Wᵢ≤ 0.5.

### Second Embodiment

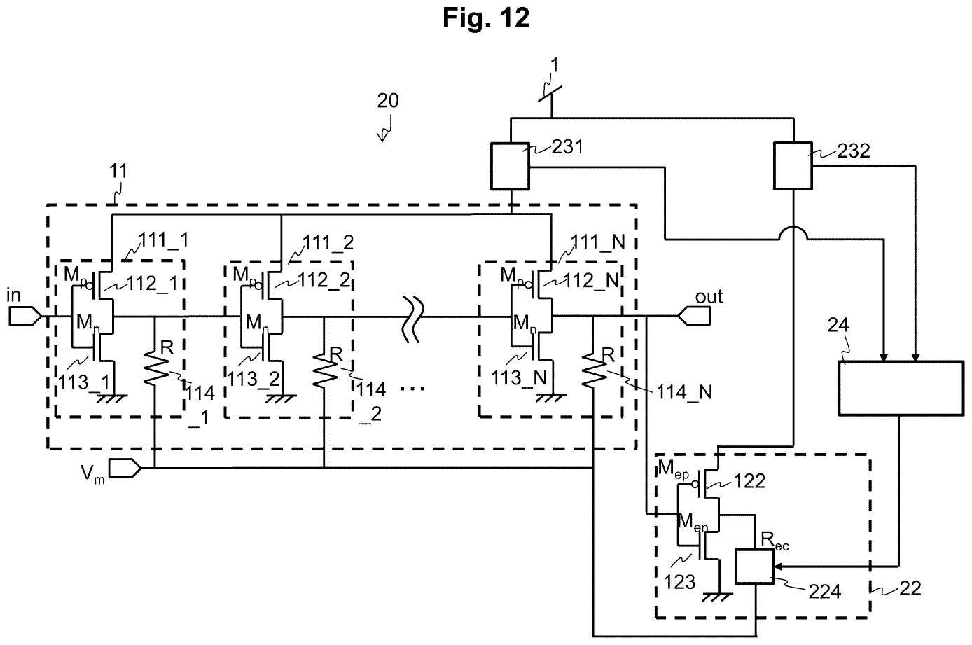

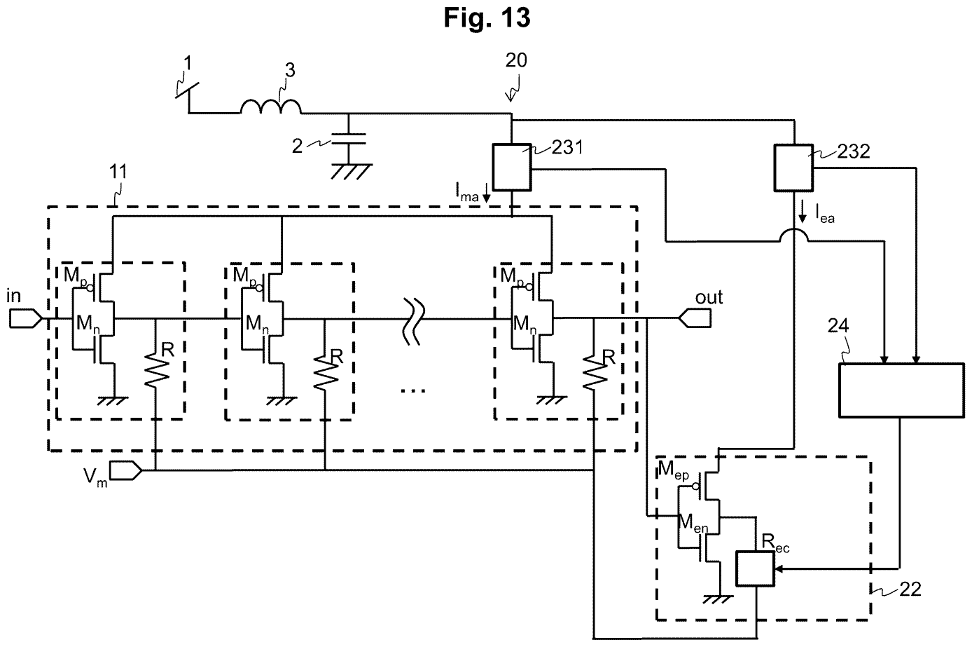

A multistage amplifier circuit according to a second embodiment of the present invention will be described with reference to FIGS. 12 and 13.

### <Configuration of Multistage Amplifier Circuit>

As illustrated in FIG. 12, a multistage amplifier circuit 20 according to the present embodiment includes a multistage amplifier 11, a power supply AC current balancing circuit 22, a first current sensor 231, a second current sensor 232, and a balancing control circuit 24.

The multistage amplifier 11 has the same configuration as in the first embodiment.

The power supply AC current balancing circuit 22 includes a p-type MOS transistor Mₑₚ 122, an n-type MOS transistor Mₑₙ 123, and a load resistor R_{ec} 224.

The configurations of the p-type MOS transistor Mₑₚ 122 and the n-type MOS transistor Mₑₙ 123 are similar to those in the first embodiment.

The variable resistor R_{ec} 224 is connected between the drains of the Mₑₚ 122 and the Mₑₙ 123 and the bias voltage Vₘ.

The first current sensor 231 and the second current sensor 232 are connected in parallel to a power supply 1.

The first current sensor 231 detects the power supply AC current of the multistage amplifier 11 and outputs a multistage amplifier AC current signal to the balancing control circuit 24.

The second current sensor 232 detects the power supply AC current of the power supply AC current balancing circuit 12 and outputs a balanced AC current signal to the balancing control circuit 24.

The balancing control circuit 24 receives the multistage amplifier AC current signal from the first current sensor 231 and the balanced AC current signal from the second current sensor 232. A control signal for controlling the variable resistor R_{ec} 224 of the power supply AC current balancing circuit 12 is generated on the basis of the multistage amplifier AC current signal and the balanced AC current signal, and is output to the variable resistor R_{ec} 224.

### <Operation of Multistage Amplifier Circuit>

The operation of the multistage amplifier circuit 20 according to the present embodiment will be described with reference to FIG. 13.

As described above, in the first embodiment, when the AC current Iₘₐ flowing through the multistage amplifier and the AC current Iₑₐ flowing through the power supply AC current balancing circuit 12 become substantially equal to each other, peaks or dips in the frequency characteristics of the output of the multistage amplifier are suppressed (FIGS. 5A and 5B).

Furthermore, when the load resistor Rₑ 124 of the power supply AC current balancing circuit 12 is changed, the magnitude of Iₑₐ changes. When Rₑ 124 is decreased, Iₑₐ is increased.

In the present embodiment, in a configuration in which Rₑ is a variable resistor (R_{ec}) 224, Iₘₐ and Iₑₐ are detected using the first current sensor 231 and the second current sensor 232, and the R_{ec} 224 is controlled such that Iₘₐ and Iₑₐ become substantially equal to each other. Accordingly, since changes in the current (Iₚₐ) flowing through the resonant circuit formed in the power supply line of the amplifier are suppressed, the occurrence of peaks or dips in the frequency characteristics of the output signal of the multistage amplifier circuit due to the resonant circuit formed in the power supply line is suppressed. In this way, the multistage amplifier circuit has good frequency characteristics.

In detail, the first current sensor 231 detects the multistage amplifier AC current Iₘₐ and outputs a multistage amplifier AC current signal to the balancing control circuit. The second current sensor 232 detects the balanced AC current Iₑₐ and outputs a balanced AC current signal to the balancing control circuit 24.

The balancing control circuit 24 outputs a control signal to the R_{ec} 224 to decrease the R_{ec} 224 when Iₘₐ>Iₑₐ. When Iₘₐ<Iₑₐ, a control signal for increasing the R_{ec} 224 is output to the R_{ec} 224. Accordingly, the R_{ec} 224 is controlled such that Iₘₐ and Iₑₐ are substantially equal to each other.

In the first embodiment, since the multistage amplifier circuit is manufactured by setting Wₑ and Rₑ in advance, it is difficult to adjust Iₘₐ and Iₑₐ to be substantially equal after manufacture.

On the other hand, in the present embodiment, after the multistage amplifier circuit is manufactured, Iₘₐ and Iₑₐ can be easily adjusted to be substantially equal by controlling the variable resistor with the balancing control circuit during operation of the multistage amplifier circuit.

According to the present embodiment, by controlling the variable resistor of the balancing control circuit, it is possible to easily suppress the occurrence of peaks or dips in the frequency characteristics of the output signal of the multistage amplifier circuit, which are caused by the resonant circuit formed in the power supply line, and to realize good frequency characteristics.

### Third Embodiment

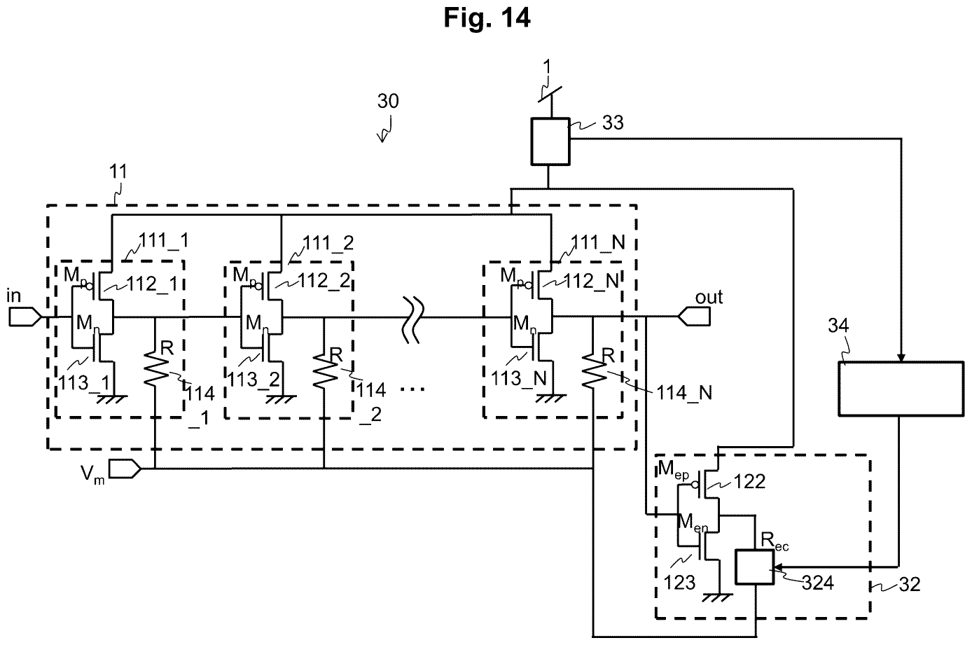

A multistage amplifier circuit according to a third embodiment of the present invention will be described with reference to FIG. 14.

### <Configuration of Multistage Amplifier Circuit>

As illustrated in FIG. 14, a multistage amplifier circuit 30 according to the present embodiment includes a multistage amplifier 11, a power supply AC current balancing circuit 32, a current sensor 33, and a balancing control circuit 34.

The multistage amplifier 11 has the same configuration as in the first embodiment. The power supply AC current balancing circuit 32 includes a p-type MOS transistor Mₑₚ 122, an n-type MOS transistor Mₑₙ 123, and a load resistor R_{ec} 324.

The configurations of the p-type MOS transistor Mₑₚ 122 and the n-type MOS transistor Mₑₙ 123 are similar to those in the first embodiment.

The variable resistor R_{ec} 324 is connected between the drains of the Mₑₚ 122 and the Mₑₙ 123 and the bias voltage Vₘ.

The current sensor 33 is connected between the power supply 1 and the multistage amplifier 11, detects a power supply AC current, and outputs a power supply AC current signal to the balancing control circuit 34.

The balancing control circuit 34 receives a power supply AC current signal from the current sensor 33. A control signal for controlling the variable resistor R_{ec} 324 of the power supply AC current balancing circuit is generated on the basis of the power supply AC current signal, and is output to the variable resistor R_{ec} 324.

### <Operation of Multistage Amplifier Circuit>

The operation of the multistage amplifier circuit 30 according to the present embodiment will be described.

As described above, in the first embodiment, when the AC current Iₘₐ flowing through the multistage amplifier 11 and the AC current Iₑₐ flowing through the power supply AC current balancing circuit 32 become equal, Iₘₐ and Iₑₐ cancel each other out, and peaks or dips in the frequency characteristics of the output of the multistage amplifier 11 are suppressed (FIGS. 5A and 5B). When Iₘₐ and Iₑₐ cancel each other out, the power supply AC current signal becomes substantially equal to zero.

In the present embodiment, in the configuration in which Rₑ is the variable resistor (R_{ec}) 324, the variable resistor R_{ec} 324 is controlled by the balancing control circuit 34 such that the power supply AC current signal becomes substantially equal to zero.

In detail, when the power supply AC current signal is not zero, that is, when it is positive or negative, the balancing control circuit 34 outputs a control signal for increasing or decreasing the R_{ec} 324 such that the power supply AC current signal becomes substantially equal to zero, thereby controlling the R_{ec} 324 such that the power supply AC current signal becomes substantially equal to zero, that is, such that Iₘₐ and Iₑₐ become substantially equal to each other.

Accordingly, since changes in the current (Iₚₐ) flowing through the resonant circuit formed in the power supply line of the amplifier are suppressed, the occurrence of peaks or dips in the frequency characteristics of the output signal of the multistage amplifier circuit due to the resonant circuit formed in the power supply line is suppressed. In this way, the multistage amplifier circuit has good frequency characteristics.

In the present embodiment, after the multistage amplifier circuit is manufactured, Iₘₐ and Iₑₐ can be easily adjusted to be substantially equal by controlling the variable resistor with the balancing control circuit during operation of the multistage amplifier circuit.

According to the present embodiment, by controlling the variable resistor of the balancing control circuit, it is possible to easily suppress the occurrence of peaks or dips in the frequency characteristics of the output signal of the multistage amplifier circuit, which are caused by the resonant circuit formed in the power supply line, and to realize good frequency characteristics.

In the embodiment of the present invention, an example has been shown in which the inverting amplifier is configured by connecting in series a p-type MOS diode disposed on the power supply side and an n-type MOS diode disposed on the ground side. However, the present invention is not limited thereto, and the inverting amplifier may be configured by connecting in series an n-type MOS diode disposed on the power supply side and a p-type MOS diode disposed on the ground side.

In the embodiments of the present invention, examples of the structure, dimensions, materials, and the like of each component in the configuration and manufacturing method of the multistage amplifier circuit are shown, but the present invention is not limited thereto. Any structures, dimensions, materials, and the like may be used as long as functions and effects of the multistage amplifier circuit are exhibited.

Note that the present invention is not limited to the above-described embodiments, and it is obvious that modifications and combinations of the above-described embodiments can be made by a person having ordinary knowledge in the art within the technical idea of the present invention.

Some or all of the above-described embodiments may be described as in the following supplementary notes, but are not limited to the following supplementary notes.

(Supplementary Note 1) A multistage amplifier circuit connected to a power supply line, the multistage amplifier circuit including: a multistage amplifier in which a plurality of inverting amplifiers are connected in multiple stages, each including p-type MOS transistors and n-type MOS transistors connected in series; and a power supply AC current balancing circuit connected to an output of a final-stage inverting amplifier among the plurality of inverting amplifiers, in which the power supply AC current balancing circuit includes: another p-type MOS transistor and another n-type MOS transistor connected in series; and a resistor connected between drains of the other p-type MOS transistor and the other n-type MOS transistor and a bias voltage.

(Supplementary Note 2) The multistage amplifier circuit according to Supplementary Note 1 and Supplementary Note 8, in which a first current flowing from the power supply line to the multistage amplifier and a second current flowing from the power supply line to the power supply AC current balancing circuit are substantially equal to each other.

(Supplementary Note 3) The multistage amplifier circuit according to any one of Supplementary Note 1, Supplementary Note 2, and Supplementary Note 8, in which a sum of a width of the other p-type MOS transistor and a width of the other n-type MOS transistor is set such that a first current flowing from the power supply line to the multistage amplifier and a second current flowing from the power supply line to the power supply AC current balancing circuit are substantially equal to each other.

(Supplementary Note 4) The multistage amplifier circuit according to any one of Supplementary Notes 1 to 3 and Supplementary Note 8, in which the resistor is set such that the first current flowing from the power supply line to the multistage amplifier and the second current flowing from the power supply line to the power supply AC current balancing circuit are substantially equal to each other.

(Supplementary Note 5) The multistage amplifier circuit according to any one of Supplementary Notes 1 to 4 and Supplementary Note 8, in which a sum of a width of the other p-type MOS transistor and a width of the other n-type MOS transistor satisfies Expression (A),

$$0.3 \leq G \times {W}_{e} ( {I}_{m a} = {I}_{e a} ) / {W}_{i} \leq 0.5 \qquad ( A )$$

where G is a gain of the amplifier, Wₑ (Iₘₐ=Iₑₐ) is a sum of a width of the other p-type MOS transistor and a width of the other n-type MOS transistor when the first current and the second current are equal, and Wᵢ is a sum of a width of the p-type MOS transistor and a width of the n-type MOS transistor.

(Supplementary Note 6) The multistage amplifier circuit according to any one of Supplementary Notes 1 to 5 and Supplementary Note 8, further including: a first current sensor disposed between the power supply line and the multistage amplifier; a second current sensor disposed between the power supply line and the power supply AC current balancing circuit; and a balancing control circuit connected to an output of the first current sensor and an output of the second current sensor, in which the resistor is a variable resistor, and the balancing control circuit generates a control signal based on an output signal of the first current sensor and an output signal of the second current sensor, and controls the resistor with the control signal.

(Supplementary Note 7) The multistage amplifier circuit according to any one of Supplementary Notes 1 to 6 and Supplementary Note 8, further including: a current sensor connected to the power supply line; and a balancing control circuit connected to an output of the current sensor, in which the resistor is a variable resistor, and the balancing control circuit generates a control signal such that an output signal of the current sensor becomes substantially equal to zero, and controls the resistor with the control signal.

(Supplementary Note 8) A multistage amplifier circuit connected to a power supply and a bias voltage source, the multistage amplifier circuit including: a multistage amplifier in which a plurality of inverting amplifiers are connected in multiple stages; and a power supply AC current balancing circuit, in which the inverting amplifiers each include p-type MOS transistors, n-type MOS transistors, and a resistor, the p-type MOS transistors and the n-type MOS transistors are connected in series between the power supply and ground, inputs of the inverting amplifier are gates of the p-type MOS transistor and the n-type MOS transistor, outputs of the inverting amplifier are drains of the p-type MOS transistor and the n-type MOS transistor, the resistor is connected between the output of the inverting amplifier and the bias voltage, the power supply AC current balancing circuit includes another p-type MOS transistor, another n-type MOS transistor, and another resistor, the other p-type MOS transistor and the other n-type MOS transistor are connected in series between the power supply and ground, the other resistor is connected between drains of the other p-type MOS transistor and the other n-type MOS transistor and the bias voltage, and an output of a final-stage inverting amplifier in the multistage amplifier is connected to gates of the other p-type MOS transistor and the other n-type MOS transistor.

(Supplementary Note 9) The multistage amplifier circuit according to any one of Supplementary Notes 1 to 8, in which a ratio of a width of the other p-type MOS transistor to a width of the other n-type MOS transistor is substantially equal to a ratio of a width of the p-type MOS transistor to a width of the n-type MOS transistor.

### INDUSTRIAL APPLICABILITY

The present invention relates to a multistage amplifier circuit, and can be applied to semiconductor devices, and communication devices and communication systems for electrical signals and optical signals.

### REFERENCE SIGNS LIST

10 Multistage amplifier circuit
11 Multistage amplifier
111_1 to 111_N Inverting amplifier
112_1 to 112_N p-type MOS transistor (Mₚ)
113_1 to 113_N n-type MOS transistor (Mₙ)
12 Power supply AC current balancing circuit
122 Another p-type MOS transistor (Mₑₚ)
123 Another n-type MOS transistor (Mₑₙ)
124 Resistor (Rₑ)

1-7. (canceled)

8. A multistage amplifier circuit connected to a power supply line, the multistage amplifier circuit comprising:
a multistage amplifier in which a plurality of inverting amplifiers are connected in multiple stages, each including p-type MOS transistors and n-type MOS transistors connected in series; and
a power supply AC current balancing circuit connected to an output of a final-stage inverting amplifier among the plurality of inverting amplifiers,
wherein the power supply AC current balancing circuit includes:
another p-type MOS transistor and another n-type MOS transistor connected in series; and
a resistor connected between drains of the other p-type MOS transistor and the other n-type MOS transistor and a bias voltage.

9. The multistage amplifier circuit according to claim 8, wherein a first current flowing from the power supply line to the multistage amplifier and a second current flowing from the power supply line to the power supply AC current balancing circuit are substantially equal to each other.

10. The multistage amplifier circuit according to claim 9, wherein a sum of a width of the other p-type MOS transistor and a width of the other n-type MOS transistor is set such that a first current flowing from the power supply line to the multistage amplifier and a second current flowing from the power supply line to the power supply AC current balancing circuit are substantially equal to each other.

11. The multistage amplifier circuit according to claim 9, wherein the resistor is set such that the first current flowing from the power supply line to the multistage amplifier and the second current flowing from the power supply line to the power supply AC current balancing circuit are substantially equal to each other.

12. The multistage amplifier circuit according to claim 9, wherein a sum of a width of the other p-type MOS transistor and a width of the other n-type MOS transistor satisfies Expression (A),
$$0.3 \leq G \times {W}_{e} ( {I}_{m a} = {I}_{e a} ) / {W}_{i} \leq 0.5 \qquad ( A )$$
where G is a gain of an inverting amplifier, Wₑ(Iₘₐ=Iₑₐ) is a sum of a width of the other p-type MOS transistor and a width of the other n-type MOS transistor when the first current and the second current are equal, and Wᵢ is a sum of a width of the p-type MOS transistor and a width of the n-type MOS transistor.

13. The multistage amplifier circuit according to claim 8, further comprising:
a first current sensor disposed between the power supply line and the multistage amplifier;
a second current sensor disposed between the power supply line and the power supply AC current balancing circuit; and
a balancing control circuit connected to an output of the first current sensor and an output of the second current sensor,
wherein the resistor is a variable resistor, and
the balancing control circuit generates a control signal based on an output signal of the first current sensor and an output signal of the second current sensor, and controls the resistor with the control signal.

14. The multistage amplifier circuit according to claim 8, further comprising:
a current sensor connected to the power supply line; and
a balancing control circuit connected to an output of the current sensor,
wherein the resistor is a variable resistor, and
the balancing control circuit generates a control signal such that an output signal of the current sensor becomes substantially equal to zero, and controls the resistor with the control signal.

15. A method of operating a multistage amplifier circuit connected to a power supply line, the method comprising:
providing a multistage amplifier in which a plurality of inverting amplifiers are connected in multiple stages, each including p-type MOS transistors and n-type MOS transistors connected in series;
connecting a power supply AC current balancing circuit to an output of a final-stage inverting amplifier among the plurality of inverting amplifiers, the power supply AC current balancing circuit including another p-type MOS transistor and another n-type MOS transistor connected in series, and a resistor connected between drains of the other p-type MOS transistor and the other n-type MOS transistor and a bias voltage;
generating a first AC current flowing from the power supply line to the multistage amplifier in response to an input signal;
generating a second AC current flowing from the power supply line to the power supply AC current balancing circuit, the second AC current being in opposite phase to the first AC current; and
balancing the first AC current and the second AC current to suppress changes in a power supply AC current that is a sum of the first AC current and the second AC current.

16. The method according to claim 15, wherein the balancing comprises setting a sum of a width of the other p-type MOS transistor and a width of the other n-type MOS transistor such that the first AC current and the second AC current are substantially equal to each other.

17. The method according to claim 15, wherein the resistor is a variable resistor, and the balancing comprises controlling the variable resistor to make the first AC current and the second AC current substantially equal to each other.

18. The method according to claim 17, further comprising:
detecting the first AC current with a first current sensor disposed between the power supply line and the multistage amplifier;
detecting the second AC current with a second current sensor disposed between the power supply line and the power supply AC current balancing circuit; and
generating a control signal based on the detected first AC current and the detected second AC current to control the variable resistor.

19. The method according to claim 15, wherein the balancing comprises making the first AC current and the second AC current substantially equal to each other such that the power supply AC current is substantially zero.

20. A multistage amplifier circuit connected to a power supply and a bias voltage source, the multistage amplifier circuit comprising:
a multistage amplifier in which a plurality of inverting amplifiers are connected in multiple stages; and
a power supply AC current balancing circuit,
wherein the inverting amplifiers each include p-type MOS transistors, n-type MOS transistors, and a resistor,
the p-type MOS transistors and the n-type MOS transistors are connected in series between the power supply and ground,
inputs of the inverting amplifiers are gates of the p-type MOS transistors and the n-type MOS transistors,
outputs of the inverting amplifiers are drains of the p-type MOS transistors and the n-type MOS transistors,
the resistor is connected between the output of each inverting amplifier and the bias voltage source,
the power supply AC current balancing circuit includes another p-type MOS transistor, another n-type MOS transistor, and another resistor,
the other p-type MOS transistor and the other n-type MOS transistor are connected in series between the power supply and ground,
the other resistor is connected between drains of the other p-type MOS transistor and the other n-type MOS transistor and the bias voltage source, and
an output of a final-stage inverting amplifier in the multistage amplifier is connected to gates of the other p-type MOS transistor and the other n-type MOS transistor.

21. The multistage amplifier circuit according to claim 20, wherein a first current flowing from the power supply to the multistage amplifier and a second current flowing from the power supply to the power supply AC current balancing circuit are substantially equal to each other.

22. The multistage amplifier circuit according to claim 20, wherein a ratio of a width of the other p-type MOS transistor to a width of the other n-type MOS transistor is substantially equal to a ratio of a width of the p-type MOS transistors to a width of the n-type MOS transistors in the inverting amplifiers.

23. The multistage amplifier circuit according to claim 20, wherein the other resistor is a variable resistor, and further comprising a balancing control circuit configured to control the variable resistor to balance AC currents flowing through the multistage amplifier and the power supply AC current balancing circuit.

24. The multistage amplifier circuit according to claim 20, wherein a sum of a width of the other p-type MOS transistor and a width of the other n-type MOS transistor satisfies the relationship:
$$0.3 \leq G \times {W}_{e} / {W}_{i} \leq 0.5$$
where G is a gain of an inverting amplifier, Wₑ is a sum of the width of the other p-type MOS transistor and the width of the other n-type MOS transistor, and Wᵢ is a sum of a width of the p-type MOS transistors and a width of the n-type MOS transistors in each inverting amplifier.
